(19) United States
(12) Patent Application Publication
(10) Pub. No.: US 2004/0107569 A1
(43) Pub. Date: Jun. 10, 2004

(54) Metal core substrate packaging

(76) Inventors: John Guzek, Chandler, AZ (US); Hamid Azimi, Chandler, AZ (US); Dustin Wood, Chandler, AZ (US)

Correspondence Address: SCHWABE, WILLIAMSON & WYATT, P.C., PACWEST CENTER, SUITES 1600-1900, 1211 SW FIFTH AVENUE, PORTLAND, OR, 97204, US

(21) Appl. No.: 10/313,932

(22) Filed: Dec. 5, 2002

(51) Int. Cl. H01L 29/00; H01L 23/48

(52) U.S. Cl. 29/846; 257/782; 257/508

(57) ABSTRACT

Apparatus and methods are provided for a rigid metal core carrier substrate. The metal core increases the modulus of elasticity of the carrier substrate to greater than 20 GPa to better resist bending loads and stresses encountered during assembly, testing and consumer handling. The carrier substrate negates the need to provide external stiffening members resulting in a microelectronic package of reduced size and complexity. The coefficient of thermal expansion of the carrier substrate can be adapted to more closely match that of the microelectronic die, providing a device more resistant to thermally-induced stresses. In one embodiment of the method in accordance with the invention, a metal sheet having a thickness in the range including 200-500 μm and a flexural modulus of elasticity of at least 20 GPa is laminated on both sides with dielectric and conductive materials using standard processing technologies to create a carrier substrate.

### FIELD OF THE INVENTION

The present invention relates to carrier substrate for microelectronic packaging, and, more particularly, to carrier substrate having a metal core.

### BACKGROUND OF INVENTION

A microelectronic package comprises a microelectronic die electrically interconnected with a carrier substrate and associated additional elements, such as electrical interconnects, a die lid, a heat dissipation device, among others. An example of a microelectronic package is an integrated circuit microprocessor. The carrier substrate provides electrically conductive pathways through which microcircuits of the microelectronic die communicate with the system substrate. A system substrate, for example a motherboard, is the platform upon which electrical components, such as microelectronic packages, are interconnected. The system board provides electrical pathways through which components communicate.

The majority of carrier substrate used today is based on an organic composite core, such as fiber-glass reinforced epoxy composite core substrate. The core is the foundation or central layer upon which substrate lamina are applied. Substrate lamina refers to layers or sheets of material used to build up the carrier substrate. Organic core carrier substrate offers a central core of dielectric material with an outstanding dielectric property but undesirable mechanical properties for particular packaging technologies. In particular, stiffness is low, and the coefficient of thermal expansion (CTE) is relatively high. This places a burden on the interconnects between the microelectronic die and the carrier substrate of accommodating structural loading due to handling as well as CTE mismatch.

Organic core carrier substrate has a typical modulus of elasticity of 9 GPa. This modulus is not sufficient to resist the structural loading conditions experienced by a microelectronic device during the fabrication and testing process as well as from consumer handling and socketing activities. Under certain loading conditions, the carrier substrate flexes under the rigid microelectronic die putting tensile, shear stress, and/or compressive stress on the interconnect material coupling the components together as well as on the microelectronic die. For example, typical loads encountered during package assembly can exceed either the strength of the interconnect material causing failure of the electrical connection or the strength of the microelectronic die causing the die to delaminate. This mismatch of flexural modulus of elasticity (an indicator of stiffness property of the material) between the microelectronic die and the carrier substrate presents microelectronic packaging reliability challenges.

Additionally, organic core carrier substrate does not have a flexural modulus of elasticity sufficient to resist the bending that results from the mismatch of CTE between the interconnected microelectronic die and carrier substrate; in general, warpage can be observed. Microelectronic dice typically have a CTE of about 3 ppm/C and epoxy-glass based carrier substrate in the range of about 16 to 21 ppm/C, depending on the glass cloth, resin system, and copper content. The mismatch in CTE contributes to thermally driven stress and can affect package reliability in many ways.

In some manner, all microelectronic packaging technologies are affected by structural loading and stresses caused by the mismatch in CTE. Furthermore, in opposition to the need for high I/O count and large microelectronic package and microelectronic die sizes, these thermally driven stresses increase with chip size. Unlike wirebond or tape automated bonding (TAB) attachment, flip chip array (FCA) packaging, for example, requires the packaging technology to form and maintain electrical interconnects between the microelectronic die and the carrier substrate over the entire face of the microelectronic die.

Stiffening plates coupled to the carrier substrate have been used to reinforce the carrier substrate to resist mechanical and thermal loading effects. The use of external stiffening structures, though, adds to the cost of the microelectronic package, as well as reduces the amount of surface area available on the carrier substrate for microelectronic die and component attachment.

The design and material characteristics of the carrier substrate play a key role in the electrical properties of the microelectronic package. Power delivery, voltage droop, and electromagnetic interference (EMI) are three of the key considerations that need to be addressed at the carrier substrate level. The AC performance is measured in terms of the change of current over time (di/dt), or switching noise. The noise on the core power supply is measured at certain instances, which are referred to as “1^{st} droop,” “2^{nd} droop,” and “3^{rd} droop.” The 1^{st} droop is generally mitigated by effective placement of high-frequency on-die and mid-frequency on-package decoupling capacitors. The 2^{nd} droop is affected by package-level and low-frequency system substrate decoupling, and the 3^{rd} droop is affected by system substrate decoupling and voltage regulation module (VRM) placement. The decoupling capacitors are required to be in close proximity to the microelectronic die which reduces the available space on the carrier substrate for the microelectronic die.

Voltage noise generated due to di/dt switching is proportional to L di/dt, where L represents the power loop inductance. The design of the power delivery network to mitigate this inductance is critical to the design of the microelectronic package. Careful consideration is required during carrier substrate design in correctly placing power and ground planes, power and ground vias, and in-capacitor pad design, to ensure low inductance power delivery loops.

Loop inductance of the power delivery network is impacted by the location and orientation of the discrete capacitors used to decouple the various components of the microelectronic package. But, the mutual inductance between the capacitors, interconnect pads, power and ground planes, and power and ground buses can significantly reduce the total effective inductance of the capacitors. Therefore, additional capacitors are needed to control the loop inductance increasing the cost and complexity of the microelectronic package.

For the reasons stated above, and for other reasons stated below which will become apparent to those skilled in the art upon reading and understanding the present specification, there is a significant need in the art for a microelectronic carrier substrate that addresses the limitations and undesirable characteristics associate with the composite core substrate.

### BRIEF DESCRIPTION OF DRAWINGS

FIG. 1 is a cross-sectional view of a rigid metal core carrier substrate, in accordance with an embodiment of the present invention;

FIG. 2 is a cross-sectional view of a commonly known 2-2-2 organic core carrier substrate;

FIG. 3 is a cross-sectional view of a rigid metal core carrier substrate, in accordance with another embodiment of the present invention;

FIG. 4 is a cross-sectional view of a rigid metal core carrier substrate, in accordance with another embodiment of the present invention;

FIG. 5 is a flow diagram of an embodiment of a method for fabricating a rigid metal core substrate in accordance with the present invention;

FIGS. 6A-C are cross-sectional views of a rigid metal core carrier substrate in various stages of production made in accordance with an embodiment of the present invention;

FIG. 7 is a table of modeled and measured performance data for organic core and metal core carrier substrate in accordance with the present invention; and

FIG. 8 is a table of measured performance data for organic core and metal core carrier substrate in accordance with the present invention.

### DESCRIPTION

In the following detailed description, reference is made to the accompanying drawings which form a part hereof wherein like numerals designate like parts throughout, and in which is shown by way of illustration specific embodiments in which the invention may be practiced. It is to be understood that other embodiments may be utilized and structural or logical changes may be made without departing from the scope of the present invention.

Embodiments in accordance with the invention provide carrier substrate and methods for fabricating carrier substrate having a rigid metal core for use in microelectronic packaging. The carrier substrate is adapted to have a flexural modulus of elasticity greater than that of conventional organic core carrier substrate. The carrier substrate comprises a metal sheet having on each side at least one conductive layer and at least one dielectric layer electrically insulating the conductive layer and the metal sheet. The conductive layers on each side of the metal sheet are interconnected with plated though holes (PTH) which extend through the metal sheet and dielectric layers and are insulated from the metal sheet.

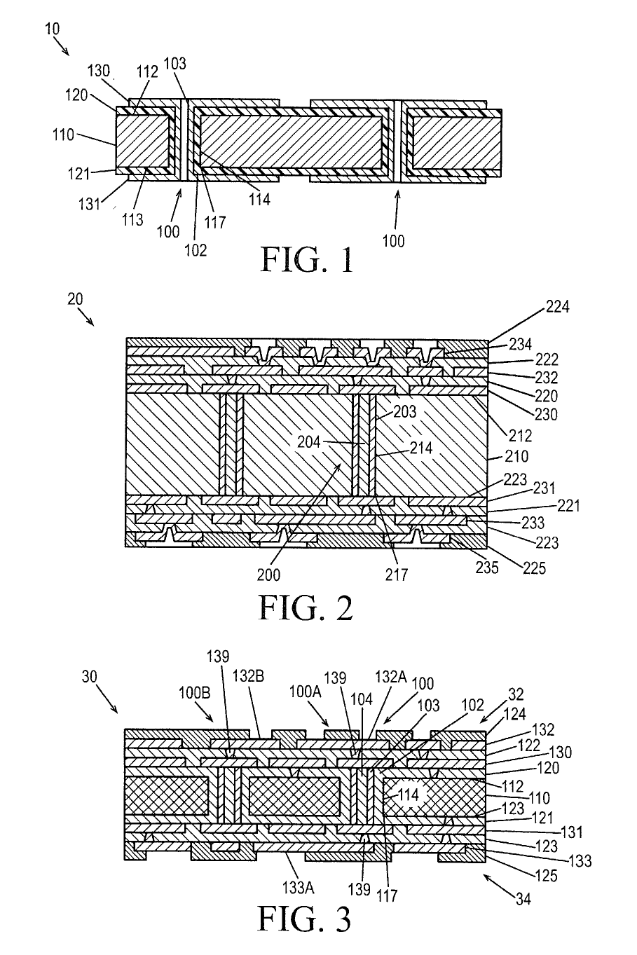

FIG. 1 is a cross-sectional view of a rigid metal carrier substrate 10, in accordance with an embodiment of the present invention. The carrier substrate 10 includes a metal core 110; one dielectric layer 120 contiguous with one conductive layer 130 and a first core surface 112 of the metal core 110; one dielectric layer 121 contiguous with one conductive layer 131 and a second core surface 113 of the metal core 110; and at least one plated through hole (PTH) 100. Each PTH 100 includes a dielectric liner 102 contiguous with a conductive liner 103 and a core through hole (CTH) wall 114 of a core through hole 117. The conductive liner 103 is adapted to establish electrical interconnection between corresponding conductive layers 130, 131 on opposite sides of the metal core 110. The dielectric liner 102 is adapted to insulate the conductive liner 103 from the metal core 110. The conductive layers 130, 131 are provided to produce a predetermined conductive pattern on the dielectric layers 120, 121, selectively isolating one PTH 100 from another. The metal core 110 is adapted to have a flexural modulus of elasticity of greater than 20 GPa.

FIG. 2 is a cross-sectional view of a commonly known 2-2-2 organic core carrier substrate 20. In contrast to the metal core carrier substrate 10 as shown in FIG. 1, the organic core carrier substrate includes a dielectric core 210; three conductive layers 230, 232, 234 and three dielectric layers 220, 222, 224 formed on a first dielectric core surface 212; three conductive layers 231, 233, 235 and three dielectric layers 221, 223, 225 formed on a second dielectric core surface 223; and at least one PTH 200. Each conductive layer 230, 231, 232, 233, 234 is disposed contiguous with at least one dielectric layer 220, 221, 222, 223, 224, 225 and/or the first and second dielectric core surfaces 212, 223.

Each PTH 200 includes a conductive liner 203 on a dielectric core through hole wall 214 of the dielectric core through hole 217. The conductive liner 203 is adapted to establish electrical interconnection between corresponding conductive layers 230, 231 on opposite sides of the dielectric core 210. The conductive layers 230, 231, 232, 233, 234 and dielectric layers 220, 221, 222, 223, 224, 225 are provided to produce a predetermined conductive pattern suitable for producing individual and isolated conductive paths within and on the carrier substrate 30. Each PTH 200 formed in the dielectric core 210 is filled with a dielectric material plug 204.

Carrier substrate is commonly identified using a three-digit numerical designation. For example, the “2-2-2” designation used for the organic core carrier substrate 20 shown in FIG. 2, is used to indicate the number of conductive layers present in a particular carrier substrate. The second digit indicates the number of conductive layers in the area spanned by the length of the PTH, including the two conductive layers in direct contact with the PTH. The first and third digits represent the number of conductive layers beyond the area spanned by the PTH. Referencing the organic core carrier substrate 20, the center digit identifies that there are two conductive layers 230, 231 along the length of the PTH 200. The first and third digits represent the number of conductive layers 232, 234; 233, 235 on either side beyond the PTH 200.

Referring again to FIG. 1, the rigid metal core carrier substrate 10 in accordance with the present invention has a three-conductive layer designation (X-3-X) adjacent the PTH 200, whereas the organic core substrate has two (X-2-X). This configuration provides numerous structural and electrical benefits over organic core substrate which will be discussed below.

FIG. 3 is a cross-sectional view of a 1-3-1 rigid metal core carrier substrate 30, in accordance with another embodiment of the present invention. The carrier substrate 30 includes a metal core 110; three dielectric layers 120, 122, 124 contiguous with two conductive layers 130, 132 and/or a first core surface 112 of the metal core 110; three dielectric layers 121, 123, 125 contiguous with two conductive layers 131, 133 and/or a second core surface 123 of the metal core 110; and at least one PTH 100. Each dielectric layer 120, 121, 122, 123, 124, 125 is disposed between one conductive layer 130, 131, 132, 133 and/or the metal core 110.

Each PTH 100 includes a dielectric liner 102 contiguous with a conductive liner 103 and a CTH wall 114 of the CTH 117. The conductive liner 103 is adapted to establish electrical interconnection between corresponding conductive layers 130, 131 on opposite sides of the metal core 110. The dielectric liner 102 is adapted to electrically insulate a conductive liner 103 from the metal core 110. Each PTH 100 formed in the metal core 110 is filled with a dielectric material plug 104. The conductive layers 130, 131, 132, 133, and dielectric layers 120, 121, 122, 123, 124, 125 are provided to produce a predetermined conductive pattern suitable for producing individual and isolated conductive paths within and on the carrier substrate 30. The metal core 110 is adapted to have a flexural modulus of elasticity of greater than 20 GPa.

Notably, among the PTH's 100, a first PTH 100A is in electrical communication with an exposed first portion 132A of conductive layer 132 via conductive layer 130 and interlayer interconnects 139. The first PTH 100A is also in electrical communication with exposed second portion 133A of conductive layer 133 via conductive layer 131 and interlayer interconnects 139, providing an electrical communication path between a carrier substrate first side 32 and a carrier substrate second side 34. Exposed first portion 132A and exposed second portion 133A are adapted to provide an interconnect pad for interconnection with electronic components, such as, but not limited to: a microelectronic die to form a microelectronic device; interconnect material to form a ball grid array package; and interconnect pins to form a pin grid array package. The dielectric layers 124, 125 on the carrier substrate first and second sides 32, 34 are used as a solder resist in some applications of the carrier substrate 30.

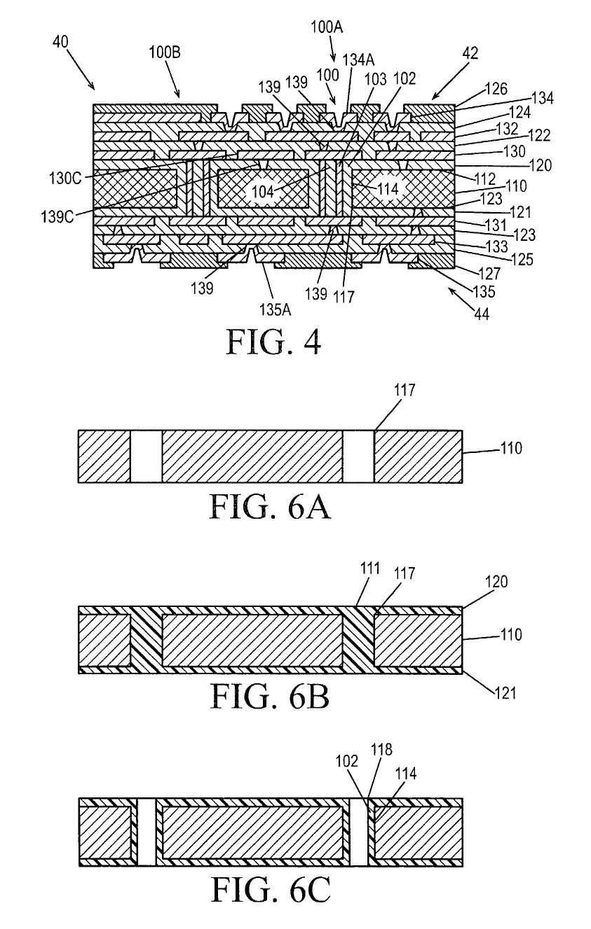

FIG. 4 is a cross-sectional view of a 2-3-2 rigid metal core carrier substrate 40, in accordance with another embodiment of the present invention. The carrier substrate 40 includes a metal core 110; four dielectric layers 120, 122, 124, 126 contiguous with three conductive layers 130, 132, 134 and/or a first core surface 112 of the metal core 110; four dielectric layers 121, 123, 125, 127 contiguous with three conductive layers 131, 133, 135 and/or a core second surface 123 of the metal core 110; and at least one PTH 100. Each dielectric layer 120, 121, 122, 123, 124, 125, 126, 127 is disposed between one conductive layer 130, 131, 132, 133, 134, 135 and/or the metal core 110.

Each PTH 100 includes a dielectric liner 102 contiguous with a conductive liner 103 and a CTH wall 114 of the CTH 117. The conductive liner 103 is adapted to establish electrical interconnection between corresponding conductive layers 130, 131 on opposite sides of the metal core 110. The dielectric liner 102 is adapted to electrically insulate the conductive liner 103 from the metal core 110. Each PTH 100 formed in the metal core 110 is filled with a dielectric material plug 104. The dielectric liner 102 is adapted to electrically insulate the conductive liner 103 from the metal core 110. Each PTH 100 formed in the metal core 110 is filled with a dielectric material plug 104. The conductive layers 130, 131, 132, 133, 134, 135 and dielectric layers 120, 121, 122, 123, 124, 125, 126, 127 are provided to produce a predetermined conductive pattern suitable for producing individual and isolated conductive paths within and/or on the carrier substrate 40. The metal core 110 is adapted to have a flexural modulus of elasticity of greater than 20 GPa.

A predetermined pattern in the outer dielectric layers 126, 127 forms openings to expose portions of the conductive layers 132, 133 below. A first PTH 100A is in electrical communication with an exposed first portion 134A of conductive layer 134 via conductive layer 130, interlayer interconnects 139 and conductive layer 132. The exposed second portion 135A of the conductive layer 135 via conductive layer 131, interlayer interconnects 139, and conductive layer 133, providing an electrical communication path between a carrier substrate first surface 42 and a carrier substrate second surface 44. Exposed first portion 134A and exposed second portion 135A are adapted to provide interconnect pads for interconnection with electronic components, such as, but not limited to, a microelectronic die to form a microelectronic device, interconnect material to form a ball grid array package, and interconnect pins to form a pin grid array package.

In an embodiment in accordance with the present invention, the metal core 110 is in electrical communication with a portion 130 C of conductive layer 130 via interlayer interconnects 139. The metal core 110 can be used to conduct heat away from a component interconnected with the portion 130 C of conductive layer 130, as well as to provide power, ground or bias voltage to a component interconnected with the portion 130 C of conductive layer 130.

The embodiments of the metal core carrier substrate 10, 30, 40 have been described to include a specified number of dielectric layers and conductive layers. However, the number of the dielectric layers and conductive layers may be modified as adequate according to a desired configuration.

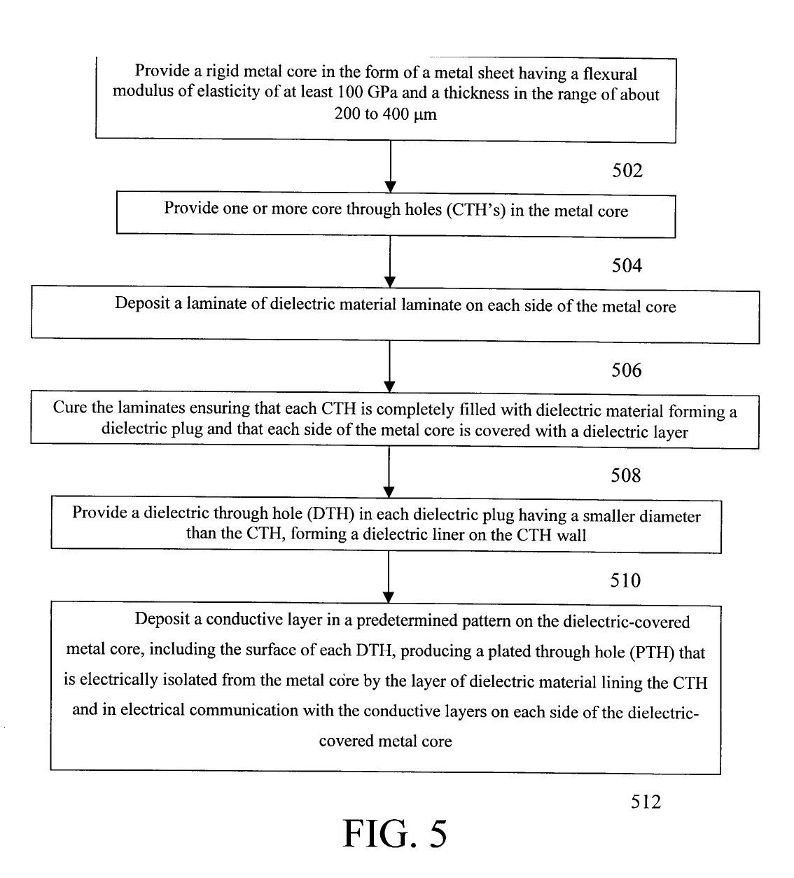

FIG. 5 is a flow diagram illustrating an embodiment of a method for fabricating a metal core carrier substrate 10 as illustrated in FIG. 1, in accordance with the present invention. The method comprises providing a rigid metal core in the form of a metal sheet having a flexural modulus elasticity of greater than 20 GPa 502. The metal sheet is provided with one or more core through holes (CTH) 504. A layer or laminate of dielectric material is deposited on both sides of the metal sheet 506. The dielectric material is cured, wherein the dielectric material flows at elevated temperature to completely fill the CTH's forming dielectric plugs therein 508. Each dielectric plug is provided with a dielectric through hole (DTH) centered on the dielectric plug in the CTH 510. The DTH is smaller in diameter than the CTH, leaving a layer of the dielectric material lining the CTH.

A conductive material is deposited in a predetermined pattern on the dielectric-covered metal core, including the surface of each DTH, producing a plated through hole (PTH) that is electrically isolated from the metal core by the layer of dielectric material lining the CTH and in electrical communication with the conductive layers on each side of the dielectric-covered metal core 512.

FIGS. 6A-C are cross-sectional views of the metal core carrier substrate 10, shown in FIG. 10, in various stages of production, in accordance with the embodiment of the method of the present invention of FIG. 5. FIG. 6A is a cross-sectional view of the metal core 110 provided with CTH's 117. FIG. 6B is a cross-sectional view of the dielectric material forming dielectric layers 120, 121 and a dielectric plug 111 within each CTH 117. FIG. 6C is a cross-sectional view of each dielectric plug 111 provided with a DTH 118. The DTH 118 defines a dielectric liner 102 on the CTH wall 114. FIG. 1 is a cross-sectional view of the completed rigid metal core carrier substrate 10 after the dielectric liner 102 and dielectric layers 120, 121 have been coated with a conductive material forming a PTH 100 and conductive layers 130, 130, respectively.

In other embodiments in accordance with the present invention, one or more additional applications of dielectric and conductive layers are built up from the carrier substrate 10 in FIG. 1, to produce rigid metal core carrier substrates, such as the rigid metal core carrier substrates 30, 40 as shown in FIGS. 3 and 4, or other configurations suitable for a particular purpose.

The metal core 110 is provided in sheet form with a thickness that imparts a flexural modulus of elasticity of 20 GPa or greater. The stiffness of the resulting carrier substrate 10, 30, 40 depends on the flexural modulus of elasticity and the thickness of the material. Examples of metals suitable for the metal core 110 include, but are not limited to, steel, stainless steel, aluminum, copper, and laminates of metals, such as copper Invar copper and copper tungsten copper, having a thickness greater than approximately 0.2 mm.

The choice of metal for the metal core 110 also depends on the particular application. For example, a metal core 110 having approximately the same coefficient of thermal expansion as the microelectronic die that is to be electrically interconnected to the carrier substrate 110 would reduce thermal induced stresses. In another application of the rigid metal core carrier substrate, the material used for the metal core 110 is chosen for a preferred heat conduction property.

The CTH 117 and DTH 118 are produced in the metal core 110 and the dielectric plug 111, respectively, using an appropriate method, including, but not limited to, drilling, etching, punching and laser ablation. Mechanical drilling is not suitable for producing through holes smaller than about 150 μm. Mechanical drilling is thus appropriate only for large-diameter through holes and larger pitches (spacing between through holes). Since it is desired for some applications to have greater than 10,000 PHT's 100 at diameters of 50 mm and smaller, advanced laser drilling processes are desirable. Laser drilling provides a high production rate of through holes with placement accuracy of about ±10 microns. Known laser drilling processes can also produce through holes with minimal wall taper.

The conductive layer comprises a material suitable for the particular purpose, including, but not limited to, copper, aluminum, gold, and silver. The conductive layers are deposited onto the dielectric material in a predetermined pattern using an appropriate method known in the art. Three suitable methods, among others, include additive, semi-additive, and subtractive lithographic techniques. To illustrate, the semi-additive lithographic technique is used to provide a conductive layer on a dielectric layer while simultaneously providing a conductive liner 103 on the dielectric liner 102. A negative pattern photoresist mask is applied on the dielectric layer, providing trenches for selective electroplating of conductive material. Electroplating deposits conductive material in the trenches while simultaneously providing a conductive liner 103 on the dielectric liner 102. After the electroplating process, the photoresist mask is removed.

The dielectric layer is deposited in predetermined patterns using an appropriate method known in the art, including, but not limited to, electrophoretic deposition and lamination. To illustrate, in one method using lamination, the dielectric material comprises one or more sheets of epoxy resin prepreg material, which, during the curing process at elevated temperature, the epoxy resin flows to cover the metal core or conductive layers and completely fill the CTH forming dielectric plugs therein.

The dielectric layers are formed from known dielectric material suitable for use in accordance with the present invention. The choice of dielectric material is selected in view of certain desirable material properties and device application. Material properties include permittivity, heat resistance, among others. Suitable dielectric materials include, but are not limited to, thermoplastic laminates, ABF, BT, polyimides and polyimide laminates, epoxy resins, epoxy resins in combination with other resin material, organic materials, alone or any of the above combined with fillers, including woven fiber matrices.

Embodiments of the rigid metal core carrier substrate in accordance with embodiments of the invention, provide carrier substrate having a metal core with a flexural modulus of elasticity of at least 20 GPa. Carrier substrate in accordance with the present invention are highly resistant to flexing under expected loading conditions, which allows the carrier substrate, and subsequent microelectronic devices, and microelectronic packages, to be handled in the assembly and test processes, as well as by the customer during socketing, without the need for an external stiffener. Negating the need for an external stiffener provides more surface area on the carrier substrate for the microelectronic die and ancillary devices, such as capacitors.

In another embodiment in accordance with the present invention, a rigid metal core with a low CTE is used to better match the CTE of the microelectronic die coupled to the substrate. This CTE-matching provides for a reduction in die stress due to thermal loading. The CTE of organic core carrier substrate is as high as approximately 40 ppm/C. The CTE of the microelectronic die can be as low as approximately 7 ppm/C. The incorporation of a rigid metal core comprising copper, having a CTE of 16 ppm/C, or alloys of copper, having a CTE as low as 4.5 ppm/C, among others, can be used in a rigid metal core carrier substrate to more closely match the CTE of the carrier substrate and microelectronic die.

The design and material characteristics of the carrier substrate play a critical role in the resulting electrical properties of the microelectronic package. Minimizing the noise on the core power supply measured at the 1^{st} droop, 2^{nd} droop, and 3^{rd} droop is of principle concern.

Design of the power delivery network to mitigate parasitic inductance is another critical aspect of power delivery design, especially at the package level, since the voltage noise generated due to di/dt switching is proportional to L di/dt, where L represents the power loop inductance. Carrier substrate design requires careful consideration to ensure low inductance power delivery loops.

The rigid metal core carrier substrate also provides buried capacitance which helps reduce simultaneous switching noise on the microelectronic die. The rigid metal core provides a low-resistance power or ground plane that improves microprocessor 3^{rd} droop performance. In addition, the metal core structure provides plated through holes for easy integration of a via-in-via design, allowing for improved package loop inductance and improved microprocessor 1^{st} droop performance.

The improved performance and design flexibility of the metal core substrate can enable designs with fewer layers, thus reducing substrate cost. For example, a 1-3-1 rigid metal core carrier substrate can be substituted for a 2-2-2 organic core carrier substrate for a lower cost.

The improved performance and design flexibility of the metal core substrate can enable the reduction of power delivery capacitors. The rigid metal core carrier substrate has a lower inductance than the organic core carrier substrate, wherein the number of decoupling capacitors can be reduced compared to an organic core carrier substrate at a fixed level of product performance.

In one embodiment of the present invention, the rigid metal core provides a path for heat dissipation due to its high thermal conductivity. Applications wherein thermal management is required, the rigid metal core can be used to distribute and disperse the heat. The thermal energy is drawn from the component coupled to the surface of the carrier substrate and flows to the metal core by way of the conductive paths formed by the metal layers and interlayer interconnects.

The rigid metal core carrier substrate 30, 40 of FIGS. 3 and 4 have been evaluated and compared with a conventional polyimide core carrier substrate 20 such as shown in FIG. 2. Electrical performance was measured and compared to determine the benefits if the metal core carrier substrates over that of the conventional carrier substrates.

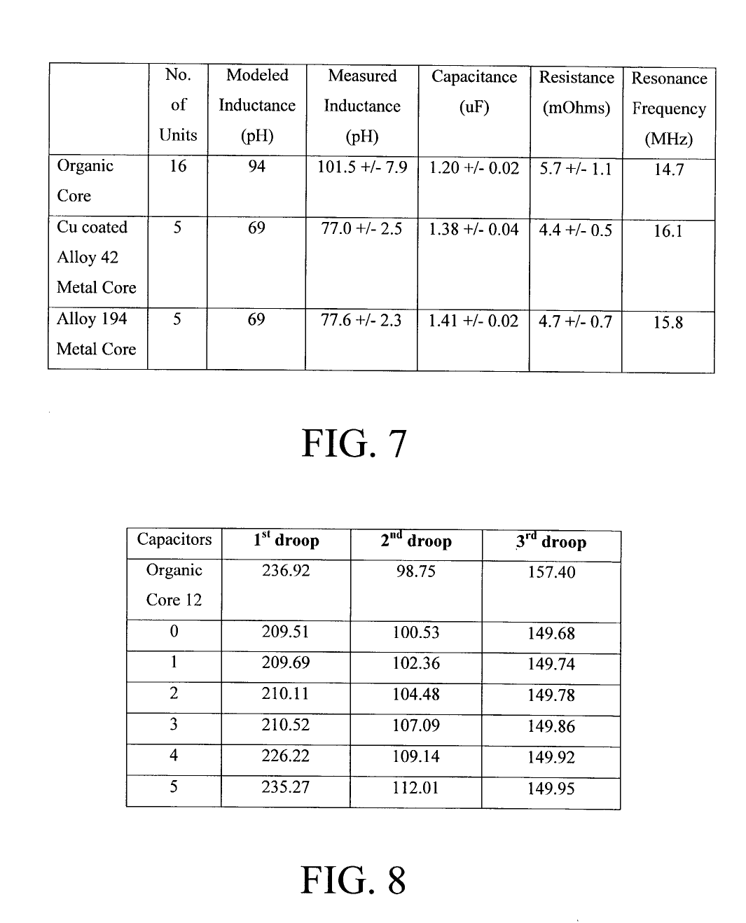

FIGS. 7 and 8 present tables showing data comparing standard 2-2-2 organic core carrier substrate with that of the 2-3-2 rigid metal core carrier substrate in accordance with the teachings of the present invention. FIG. 7 is a table of results of modeled and measured data showing reduced loop inductance for a model unit cell. Further, the rigid metal core carrier substrate exhibits a higher capacitance, lower resistance, and a higher resonance frequency.

FIG. 8 is a table of results comparing 1^{st}, 2^{nd}, and 3^{rd} droop performance of the 2-3-2 rigid metal core carrier substrate as capacitors are removed, compared to the 2-2-2 organic core carrier substrate. It is clearly shown that for 1^{st} droop performance, the rigid metal core carrier substrate with 5 less capacitors performs similarly to the organic core carrier substrate. Advantages of the metal core carrier substrate are also seen in the 3^{rd} droop performance.

The methods of the invention are compatible with the existing equipment infrastructure for substrate fabrication and therefore, do not require any major new equipment expenditures.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiments shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that only the claims and their equivalents limit this invention.

What is claimed is:

1. A method of making a rigid metal core carrier substrate, comprising:
providing a metal core in the form of a metal sheet having a first side, an opposite second side, and at least one through hole, the metal core having a flexural modulus of elasticity of at least 20 GPa;
forming dielectric layers by depositing a dielectric material in a predetermined pattern on the first side, the second side, and each through hole forming a dielectric plug within the through hole;
forming a through hole in the dielectric plug having a diameter smaller than the core through hole forming a dielectric liner;
forming a conductive liner by depositing a conductive material on the dielectric liner defining a plated through hole, the conductive liner insulated from the metal core by the dielectric liner; and
depositing a conductive material in a predetermined pattern on the dielectric layers.

2. The method of claim 1, wherein depositing a dielectric material on the first side, the second side, and the through hole forming a dielectric layer on the first and second sides, and forming a dielectric plug comprises:
covering the first and second side with a laminate of dielectric material; and
curing the laminate at elevated temperature forming a dielectric layer on the first and second side, a portion of the laminate flowing into and plugging the through holes.

3. The method of claim 1, further comprising forming one or more conductive traces on the first and second sides and in electrical communication with predetermined one or more plated through holes.

4. The method of claim 3, wherein forming one or more conductive traces on the first and second sides and in electrical communication with predetermined one or more plated through holes comprises:
forming one or more conductive traces on the first and second sides and in electrical communication with predetermined one or more plated through holes using an additive, semi-additive, or subtractive plating process

5. The method of claim 3, further comprising:
depositing additional one or more dielectric and/or conductive layers on the first and second sides;
producing one or more interlayer interconnects between one or more conductive layers; and
forming one or more conductive traces on predetermined one or more dielectric layers on the first and second sides and in electrical communication with the one or more interlayer interconnects using an additive, semi-additive, or subtractive plating process.

6. The method of claim 1, wherein providing a metal sheet comprises providing a metal sheet having a thickness of at least 200 μm comprising a material selected from the group consisting of copper, silver, aluminum, steel, and gold.

7. A method of making a metal core substrate, comprising:
providing a metal core in the form of a metal sheet having a first side, an opposite second side, and at least one through hole, the metal core having a flexural modulus of elasticity of at least 100 GPa;
covering the first and second side and each through hole with a laminate of dielectric material;
curing the laminate at elevated temperature forming a dielectric layer on the first and second side, a portion of the laminate flowing into and plugging the through holes;
forming dielectric through holes in the plug having a diameter smaller that the conductive through hole, and
depositing a conductive layer on each dielectric liner forming a plated through hole, the conductive layer insulated from the metal core by the dielectric liner.

8. The method of claim 7, further comprising forming one or more conductive traces on the first and second sides and in electrical communication with predetermined one or more plated through holes.

9. The method of claim 8, wherein forming one or more conductive traces on the first and second sides and in electrical communication with predetermined one or more plated through holes comprises:
forming one or more conductive traces on the first and second sides and in electrical communication with predetermined one or more plated through holes using an additive, semi-additive, or subtractive plating process.

10. The method of claim 7, wherein providing a metal sheet comprises providing a metal sheet having a thickness of at least 200 μm comprising a material selected from the group consisting of copper, silver, aluminum, steel, and gold.

11. A method of making a metal core carrier substrate, comprising:
providing a metal core in the form of a metal sheet having a first side, an opposite second side, and at least one core through hole, the metal core having a flexural modulus of elasticity of at least 20 GPa;
depositing a dielectric material on the first side, the second side, and in each core through hole forming a dielectric layer on the first and second sides, and forming a dielectric plug in each core through hole;
forming a dielectric liner in each core through hole by providing a dielectric though hole in the dielectric plug and centered within the core through hole, the dielectric through hole having a diameter smaller than the core through hole; and
depositing a conductive material on each dielectric liner forming a conductive liner defining a plated through hole, the conductive liner insulated from the metal core by the dielectric liner.

12. The method of claim 11, wherein depositing a dielectric material on the first side, the second side, and the core through hole forming a dielectric layer on the first and second sides, and forming a dielectric plug within each core through hole comprises:
covering the first side and second side with a laminate of dielectric material; and
curing the laminate at elevated temperature forming a dielectric layer on the first and second side, a portion of the laminate flowing into and plugging the core through holes.

13. The method of claim 11, further comprising forming one or more conductive layers on the first and second sides and in electrical communication with predetermined one or more plated through holes.

14. The method of claim 13, wherein forming one or more conductive layers on the first and second sides comprises forming one or more conductive traces on the first and second sides forming a circuit pattern.

15. The method of claim 14, wherein forming one or more conductive traces on the first and second sides forming a circuit pattern comprises forming one or more conductive traces on the first and second sides forming a circuit pattern using a process selected from the group consisting of discrete wiring, and subtractive, semi-additive, additive lithographic techniques.

16. The method of claim 13, further comprising:
depositing additional one or more dielectric and/or conductive layers in an alternating pattern on the first and second sides;
producing one or more bore holes between one or more conductive layers;
depositing a conductive material in the bore holes to electrically interconnect one conductive layer to another conductive layer; and
forming one or more conductive traces on predetermined one or more dielectric layers on the first and second sides and in electrical communication with the conductive material within predetermined one or more bore holes using an additive, semi-additive, or subtractive plating process.

17. The method of claim 11, wherein providing a metal sheet comprises providing a metal sheet having a thickness of at least 200 μm comprising a material selected from the group consisting of copper, silver, aluminum, steel, and gold.

18. A rigid metal core carrier substrate, comprising:
a metal core comprising a metal sheet having a first side and a second side, the metal sheet having a thickness in the range including 200-500 μm and a flexural modulus of elasticity of at least 20 GPa;
at least one dielectric layer covering the first side and the second side;
at least one conductive layer covering the dielectric layer on the first and second side; and
a plurality of plated through holes, the plated through holes comprising a tubular-shaped dielectric liner and a conductive liner lining the inside surface of the dielectric liner, the plated through holes extending through the metal sheet and the dielectric layers covering the first and second sides, the conductive liner in electrical communication with the conductive layer on the first and second side, the dielectric liner insulating the metal sheet from the conductive liner.

19. The rigid metal core carrier substrate of claim 18, further comprising:
additional one or more dielectric and/or conductive layers on the first and second sides; and
at least one interlayer interconnects between and in electrical communication with one or more conductive layers or the metal sheet.

20. The rigid metal core carrier substrate of claim 18, wherein the metal sheet comprises a material selected from the group consisting of copper, silver, aluminum, steel, and gold.

21. A high flexural modulus of elasticity microelectronic device, comprising:
a metal core having at least one clearance formed there through, the metal core having a thickness in the range including 200-500 μm and a flexural modulus of elasticity of at least 20 GPa;
at least one dielectric layer disposed on each of top and bottom surfaces of the metal core;
at least one conductive layer disposed on each of the dielectric layers;
at least one conductive via electrically connecting the conductive layers, the conductive via electrically insulated from the metal core, the substrate adapted to electrically and mechanically interconnect with a microelectronic die; and
a microelectronic die electrically and mechanically interconnected to at least one of the at least one conductive layer.

22. The high flexural modulus of elasticity microelectronic device of claim 21, further comprising at least one interlayer interconnect between and in electrical communication with one or more conductive layers or the metal sheet.

23. The high flexural modulus of elasticity microelectronic device of claim 21, wherein the metal sheet comprises a material selected from the group consisting of copper, silver, aluminum, steel, and gold.
